(19) United States
(12) Patent Application Publication
(10) Pub. No.: US 2014/0345921 A1
(43) Pub. Date: Nov. 27, 2014

(54) NANO WIRE COMPOSITION AND METHOD FOR FABRICATION TRANSPARENT ELECTRODE

(71) Applicant: LG INNOTEK CO., LTD., Seoul (KR)

(72) Inventors: Jong Woon Moon, Seoul (KR); Sun Young Lee, Seoul (KR); Bo Ra Kang, Seoul (KR); Young Sun You, Seoul (KR); Kyoung Hoon Chai, Seoul (KR)

(21) Appl. No.: 14/368,238

(22) PCT Filed: Dec. 12, 2012
(86) PCT No.: PCT/KR2012/010810

§ 371 Date: Jun. 23, 2014

(30) Foreign Application Priority Data
Dec. 21, 2011 (KR) 10-2011-0139611

(51) Int. Cl. H01B 1/22; H05K 1/09; H01B 13/00; H05K 1/02

(52) U.S. Cl. CPC H01B 1/22; H05K 1/0274; H05K 1/097; H01B 13/0016; Y10S 977/783; Y10S 977/89; Y10S 977/932; B82Y 40/00
USPC 174/257; 252/514; 427/125; 977/783; 977/890; 977/932

(57) ABSTRACT

Disclosed are a nanowire composition and a method of fabricating a transparent electrode. The nanowire composition includes a metallic nanowire, an organic binder, a surfactant, and a solvent. The metallic nanowire has a diameter of 30 nm to 50 nm, and a length of 15 μm to 40 μm, and a weight percentage of the metallic nanowire is in a range of 0.01% to 0.4%. The method of fabricating the transparent electrode includes preparing a nanowire composition, coating the nanowire composition on a substrate, and performing heat treatment with respect to the nanowire composition. The nanowire composition includes a metallic nanowire, an organic binder, a surfactant, and a solvent, and the metallic nanowire has a diameter of 30 nm to 50 nm, a length of 15 μm to 40 μm, and a weight percentage of 0.01% to 0.4%.

### TECHNICAL FIELD

The disclosure relates to a nanowire composition and a method of fabricating a transparent electrode.

### BACKGROUND ART

Recently, a touch panel, which performs an input function through the touch of an image displayed on a display device by an input device such as a stylus pen or a hand, has been applied to various electronic appliances.

The touch panel may be mainly classified into a resistive touch panel and a capacitive touch panel. In the resistive touch panel, glass is shorted with an electrode due to the pressure of the input device so that a touch point is detected. In the capacitive touch panel, the variation in capacitance between electrodes is detected when a finger of the user is touched on the capacitive touch panel, so that the touch point is detected.

Indium tin oxide (ITO), which has been most extensively used as an electrode of the touch panel, is highly priced, and requires a high-temperature deposition process and a vacuum process for the purpose of forming an electrode. In addition, the ITO is physically easily struck due to the bending or the curving of a substrate, so that the characteristic of the ITO for the electrode is deteriorated. Accordingly, the ITO is not suitable for a flexible device.

In order to solve the problem, researches and studies on an alternative electrode have been actively carried out.

### DISCLOSURE OF INVENTION

### Technical Problem

The embodiment provides a nanowire composition representing improved dispersibility and an improved coating property and a transparent electrode representing high transmittance and low resistance.

### Solution to Problem

According to the embodiment, there is provided a nanowire composition including a metallic nanowire, an organic binder, a surfactant, and a solvent. The metallic nanowire has a diameter of about 30 nm to about 50 nm, a length of about 15 μm to about 40 μm, and a weight percentage in a range of about 0.01% to about 0.4%.

According to the embodiment, there is provided a method of fabricating a transparent electrode. The method includes preparing a nanowire composition, coating the nanowire composition on a substrate, and performing heat treatment with respect to the nanowire composition. The nanowire composition includes a metallic nanowire, an organic binder, a surfactant, and a solvent, and the metallic nanowire has a diameter of about 30 nm to about 50 nm, a length of about 15 μm to about 40 μm, and a weight percentage of about 0.01% to about 0.4%.

### Advantageous Effects of Invention

As described above, the nanowire composition according to the embodiment includes a nanowire, an organic binder, and a surfactant serving as an additive. Accordingly, the dispersibility can be improved due to the organic binder in the coating process for the substrate. In addition, the surface tension can be reduced due to the fluorine-based surfactant, so that the coating property can be improved.

In addition, the electrode fabricated through the method of fabricating the transparent electrode according to the embodiment employs a nanowire having a diameter of 30 nm to 50 nm and a length of 15 μm to 40 μm, and includes an organic binder and a fluorine-based surfactant.

Accordingly, when the transparent electrode fabricated through the fabricating method has higher electrical conductivity, the transparent electrode can represent the higher light transmittance and the lower haze. In addition, since the electrode has the low surface resistance, the performance of the touch panel and the liquid crystal display having the electrode applied thereto can be improved.

### BRIEF DESCRIPTION OF DRAWINGS

FIG. 1 is a flowchart showing a method of fabricating a transparent electrode according to the embodiment.

### MODE FOR THE INVENTION

In the description of the embodiments, it will be understood that, when each layer (film), a region, a pattern, or a structure is referred to as being “on” or “under” a substrate, another layer (film), another region, another pad, or another pattern, it can be “directly” or “indirectly” on the other layer (film), the other region, the other pattern, or the other structure, or one or more intervening layers may also be present. Such a position of each layer has been described with reference to the drawings.

The thickness and size of each layer (film), each region, each pattern, or each structure shown in the drawings may be exaggerated, omitted or schematically drawn for the purpose of convenience or clarity. In addition, the size of the layer (film), the region, the pattern, or the structure does not utterly reflect an actual size.

A nanowire composition according to the embodiment may include a metallic nanowire, an organic binder, a surfactant, and a solvent.

The metallic nanowire may include a silver nanowire. The nanowire may be fabricated through the following method.

The method of fabricating the silver nanowire may include the steps of heating a solvent, adding a capping agent to the solvent, adding a catalyst to the solvent, adding metallic compound in the solvent, adding a room-temperature solvent to the solvent, and refining the nanowire. The steps are not essential steps, parts of the steps may not be performed according to the fabricating method, and the sequence of the steps may be changed. Hereinafter, each step will be described in more detail.

According to the step of heating the solvent, the solvent is heated at the reaction temperature suitable for forming the metallic nanowire.

The solvent may include polyol. The polyol serves as a mile reducing agent while serving as a solvent of mixing different materials to help the formation of the metallic nanowire. For example, the polyol may include ethylene glycol (EG), propylene glycol (PG), glycerine, glycerol, or glucose. The reaction temperature may be variously adjusted by taking the types and the characteristics of solvents and the metallic compounds into consideration.

Thereafter, in the step of adding the capping agent to the solvent, the capping agent inducing the forming of the wire is added to the solvent. If reduction for the forming of the nanowire is rapidly performed, metals are aggregated, so that the wire shape may not be formed. Accordingly, the capping agent prevents the metals from being aggregated by properly dispersing materials contained in the solvent.

The capping agent may include various materials. For example, the capping agent may include material selected from the group consisting of polyvinylpyrrolidone (PVP), polyvinyl alcohol (PVA), cetyl trimethyl ammonium bromide (CTAB), cetyl trimethyl ammonium chloride (CTAC), and polyacrylamide (PAA).

Thereafter, in the step of adding the catalyst to the solvent (step ST130), bay salt, refined salt, or halogen metal such as AgCl, PtCl2, PdCl2, or AuCl3 is added as the catalyst. The catalyst includes various metals or halogen elements to form a seed used to form a metallic nanowire or to accelerate the reaction of forming the metallic nanowire.

Thereafter, in the step of adding the metallic compound to the solvent, a reaction solution is formed by adding the metallic compound to the solvent.

In this case, the metallic compound melted in a separate solvent may be added to the solvent having the capping agent and the catalyst. The separate solvent may include a material identical to or different from a material in the solvent used in the initial stage. In addition, the metallic compound may be added after a predetermined time elapses from a time in which the catalyst is added. Accordingly, a desirable reaction temperature can be stabilized.

In this case, the metallic compound includes a compound including metal used to manufacture a desirable metallic nanowire. In order to form a silver nanowire, the metallic compound may include AgCl, AgNO3 or KAg(CN)2.

As described above, if the metallic compound is added to the solvent having the capping agent and the catalyst, reaction occurs so that the forming of the metallic nanowire is started.

Thereafter, in the step of adding the room-temperature solvent to a reaction solution, the room-temperature solvent is added to the solvent in which reaction is started. The room-temperature solvent may include material identical to or different from material contained in the solvent used in the initial stage.

As the solvent, in which the reaction is started, is continuously heated in order to maintain the constant reaction temperature, the temperature may be increased in the process of the reaction. As described above, the reaction temperature may be more constantly maintained by temporarily degrading the temperature of the solvent by adding the room-temperature solvent to the solvent in which the reaction is started.

The step of adding the room-temperature solvent may be performed one time or several times by taking the reaction time, and the temperature of the reaction solution into consideration.

Thereafter, in the step of refining the nanowire, the metallic nanowire is refined and collected in the reaction solution.

The nanowire formed through the above steps may have a diameter of about 30 nm to about 50 nm, and may have a length of about 15 μm to about 40 μm.

If the diameter of the nanowire is less than 15 μm, the network of the nanowire may not be formed. If the diameter of the nanowire is less than 30 nm, the diffusion-reflection may be increased due to the particles produced during the refining process of the nanowire.

In this case, the nanowire may have the content of about 0.01 weight % to about 0.4 weight % with respect to the whole content of the nanowire composition. In other words, the weight percentage of the nanowire may be in the range of 0.01% to 0.4%. If the nanowire has the content of less than 0.01 weight % with respect to the whole content of the nanowire composition, electrical conductivity may be degraded. In addition, if the nanowire has the content of more than 0.4 weight % with respect to the content of the electrode material, the nanowires are aggregated together, so that the transmittance may be degraded.

The organic binder may include aqueous cellulose having molecular weight of 100,000 or more. Preferably, the organic binder may include at least one of hydroxy propyl methyl cellulose, hydroxy propyl cellulose, xanthan gum, polyvinyl alcohol, carboxyl methyl cellulose, and hydroxy ethyl cellulose.

In this case, the organic binder may have the content of about 0.01 weight % to about 0.5 weight % with respect to the whole content of the nanowire composition. In addition, the organic binder may have the content equal to that of the nanowire.

The surfactant may include at least one of silicon-based surfactant and fluorine-based surfactant. The silicon-based surfactant can represent higher wetting and leveling effects even if a smaller amount of silicon-based surfactant is added. In addition, the fluorine-based surfactant has a fluorocarbon-chain serving as a hydrophobic group. The fluorine-based surfactant can significantly reduce the surface tension of a composition when comparing with hydrocarbon-based surfactant. In addition, when a smaller amount of fluorine-based surfactant is added, the higher surfactant effect can be represented. In addition, since the fluorocarbon-chain is chemically and thermally stabilized, the fluorocarbon-chain represents superior chemical resistance and superior heat resistance.

According to the nanowire composition of the embodiment, the surfactant may have the content of about 0.000001 weight % to about 0.001 weight % with respect to the whole content of the nanowire composition. In addition, the surfactant may have the content of about 0.0002 weight % to about 10 weight % with respect to the nanowire.

The solvent may include water or polyol. The polyols may serve as a solvent to mix different materials with each other. For example, the polyol may include ethylene glycol (EG), propylene glycol (PG), glycerine, glycerol, or glucose.

The weight percentage of the solvent may be about 99.1 weight % to about 99.98 weight %.

The nanowire composition is coated on the substrate or the glass to form a transparent electrode. In other words, a transparent conductive base can be fabricated with a transparent electrode by using the nanowire composition. In addition, an over coating layer is additionally formed on the transparent conductive base to improve the light transmittance while serving as a protective layer.

Hereinafter, a method of fabricating the transparent electrode according to the disclosure will be described in detail with reference to accompanying drawings. For the clearer explanation, the parts the same as the above-description of the nanowire composition may be omitted. In other words, the description of the method of fabricating the transparent electrode will be incorporated in the above-description of the nanowire composition.

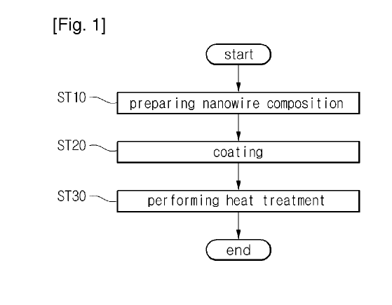

Referring to FIG. 1, the method of fabricating the transparent electrode according to the embodiment may include a step of preparing a nanowire (step ST10), a step of coating nanowire composition on a substrate (step ST20), and a step of performing heat treatment with respect to the substrate (step ST30).

In the step of preparing the nanowire composition (step ST10), the nanowire composition including nanowire, an organic binder, a surfactant, and a solvent can be prepared. The nanowire may include silver nanowire, and the nanowire may have a diameter of about 30 nm to about 50 nm, and a length of about 15 μm to about 40 μm. In this case, nanowire may have the content of about 0.01 weight % to about 0.4 weight % with respect to the whole content of the nanowire. In other words, the weight percentage of the nanowire may be in the range of about 0.01% to about 0.4%.

In addition, the organic binder may include at least one of hydroxy propyl methyl cellulose, hydroxy propyl cellulose, methyl cellulose, xanthan gum, polyvinyl alcohol, carboxyl methyl cellulose, and hydroxy ethyl cellulose. In addition, the organic binder may have the content of about 0.01 weight % to about 0.5 weight % with respect to the whole content of the nanowire. In other words, the weight percentage of the organic binder may be in the range of about 0.01% to about 0.5%.

In addition, the surfactant may include fluorine-based surfactant or silicon-based surfactant. In this case, the surfactant may have the content of about 0.000001 weight % to about 0.001 weight % with respect to the whole content of the nanowire composition. In other words, the weight percentage of the surfactant may be in the range of about 0.000001% to about 0.001%.

In addition, the solvent may include water or PG, and may have the content of about 99.1 weight % to about 99.98 weight % with respect to the whole content of the nanowire composition. In other words, the weight percentage of the solvent may be in the range of about 99.1% to about 99.98%.

Subsequently, the step of coating the nanowire composition on the substrate (step ST20), the nanowire composition may be coated on the substrate.

Since the nanowire composition includes the organic binder and the surfactant, the dispersion stability can be improved. In addition, since the surficial tension of the nanowire composition can be lowered, the nanowire may be coated on the substrate in the state that the nanowires are not aggregated together but uniformly dispersed. Therefore, the transmittance of the transparent electrode including the nanowires can be improved, and the resistance of the transparent electrode can be reduced.

In the step of coating the nanowire composition on the substrate (step ST20), a slot die coating scheme may be performed. The slot die coating scheme is one of coating schemes. According to the slot die coating scheme, a liquid-phase fluid having liquidity is supplied between the upper and lower mold plates designed and processed in a mold according to the rheology employing a slot die, so that the fluid supplied from the a fluid supplying pipe is uniformly coated at a constant thickness widthwise along a flowing direction of the fluid on the substrate.

However, the embodiment is not limited thereto, and various coating schemes, such as a spin coating scheme, a flow coating scheme, a spray coating scheme, a dip coating scheme, and a roll coating scheme, can be formed in the step of forming the nanowire composition on the substrate (step ST20).

Next, in the step of performing heat treatment with respect to the substrate (step ST30), the substrate may be subject to heat treatment.

In detail, after the nanowire composition is coated on the substrate and the substrate is dried at the aspheric condition, a temperature may be boosted. Thereafter, the heat treatment is performed at the temperature of about 50° C. to 150° C. for about 1 minute or about 10 minutes.

After coating the nanowire composition (step ST20), a process of forming an over coating layer on the nanowire may be additionally performed. The over coating layer may serve as a protective layer of the metallic nanowire coated on the substrate to prevent the metallic nanowire from being oxidized. The over coating layer may include acrylic-based polymer or urethane-based polymer, and may be formed through various schemes such as a roll coating scheme, or a slot die coating scheme. However, the over coating scheme is not essentially required, but the coated substrate may be instantly subject to the heat treatment without the over coating step.

The electrode fabricated through the method of fabricating the transparent electrode according to the embodiment can maintain high transmittance. In addition, the electrode represents low reflectance and high electrical conductivity. In addition, the electrode represents high light transmittance and low haze. Further, since the electrode has low surface resistance, the performance of the touch panel or the liquid crystal display having the electrode applied thereto can be improved.

Hereinafter, the disclosure will be described in more detail through the embodiments. However, the embodiments are provided only for the illustrative purpose, and the disclosure is not limited thereto.

### Embodiment 1

A silver nanowire composition, which includes 0.3 weight % of a silver nanowire, 0.2 weight % of hydroxy methyl cellulose having the molecular weight of 120,000 and serving as an organic binder, 0.001 weight % of F410 (produced in D.I.C., Inc.) serving as a surfactant, and water serving as a solvent, was fabricated.

Thereafter, the silver nanowire composition was coated on the substrate through a slot-die coating scheme.

Thereafter, a transparent electrode was formed on the substrate by drying the solvent through the heat treatment at the temperature of 100° C. for 100 minutes.

In this case, the silver nanowire had a diameter of 40 nm and a length of 30 μm.

### Embodiment 2

According to embodiment 2, the transparent electrode was formed on the substrate through the same manner as that of embodiment 1 except that the silver nanowire composition includes 0.5 weight % of silver nanowire.

### Embodiment 3

According to embodiment 3, the transparent electrode was formed on the substrate through the same manner as that of embodiment 1 except that the silver nanowire composition includes 0.2 weight % of hydroxy propyl cellulose having the molecular weight of 1,000,000 and serving as an organic binder.

### Embodiment 4

According to embodiment 4, the transparent electrode was formed on the substrate through the same manner as that of embodiment 1 except that the silver nanowire composition includes 0.5 weight % of silver nanowire and 0.5 weight % of hydroxy propyl cellulose having the molecular weight of 1,000,000 and serving as an organic binder.

### Embodiment 5

According to embodiment 5, the transparent electrode was formed on the substrate through the same manner as that of embodiment 1 except that the silver nanowire composition includes 0.2 weight % of carboxyl methyl cellulose having the molecular weight of 120,000 and serving as an organic binder.

### Embodiment 6

According to embodiment 6, the transparent electrode was formed on the substrate through the same manner as that of embodiment 1 except that the silver nanowire composition includes 0.5 weight % of silver nanowire and 0.5 weight % of carboxyl methyl cellulose having the molecular weight of 120,000 and serving as an organic binder.

### Embodiment 7

According to embodiment 7, the transparent electrode was formed on the substrate through the same manner as that of embodiment 1 except that the silver nanowire composition includes 0.3 weight % of hydroxy ethyl cellulose having the molecular weight of 1,000,000 and serving as an organic binder.

### Embodiment 8

According to embodiment 8, the transparent electrode was formed on the substrate through the same manner as that of embodiment 1 except that the silver nanowire composition includes 0.5 weight % of silver nanowire and 0.3 weight % of hydroxypropyl cellulose having the molecular weight of 1,000,000 and serving as an organic binder.

### Embodiment 9

According to embodiment 9, the transparent electrode was formed on the substrate through the same manner as that of embodiment 1 except that the silver nanowire composition includes 0.4 weight % of silver nanowire and 0.3 weight % of hydroxy ethyl cellulose having the molecular weight of 1,300,000 and serving as an organic binder.

The characteristics of the transparent electrode fabricated according to embodiments 1 to 9 are measured. The dispersibility, the coating property, the haze, the transmittance, and the resistance are measured with respect to embodiments 1 to 9, and the measurement results are shown in table 1.

TABLE 1

| | | coating | haze | transmittance | resistance |
|---|---|---|---|---|---|
| | dispersibility | property | (%) | (%) | (Ω/□) |
| Embodyment | 8 | 8 | 1.16 | 90.08 | 59 |
| 1 | | | | | |
| Embodyment | 8 | 9 | 1.85 | 88.67 | 39 |
| 2 | | | | | |
| Embodyment | 8 | 8 | 1.06 | 90.32 | 107 |
| 3 | | | | | |
| Embodyment | 8 | 7 | 1.68 | 89.04 | 45 |
| 4 | | | | | |
| Embodyment | 10 | 4 | 1.34 | 90.25 | 200 |
| 5 | | | | | |
| Embodyment | 10 | 2 | 2.39 | 88.25 | 57 |
| 6 | | | | | |
| Embodyment | 10 | 4 | 1.29 | 90.36 | 120 |
| 7 | | | | | |
| Embodyment | 10 | 2 | 2.48 | 88.19 | 154 |
| 8 | | | | | |
| Embodyment | 4 | 6 | 1.80 | 89.28 | 55 |
| 9 | | | | | |

(In table 1, the dispersibility is represented as the value of 10 (completely dispersed) to 1 (not dispersed), and the coating property is represented as the value of 10 (completely and uniformly coated) to 1 (not coated).

Referring to table 1, the substrates according to the first to fourth embodiments represent the superior dispersibility, the superior coating property, the low haze, and the superior transmittance. Further, although the substrates according to embodiments 5 to 8 represent the superior dispersibility, but the degraded coating property. Therefore, if the content of the silver nanowire is in the range of 0.3 weight % to 0.5 weight %, and the content of the organic binder is 0.1 weight % or more, the nanowire composition represents the superior dispersibility, the superior coating property, the high transmittance, and the low haze. In addition, since the electrode represents the low surface resistance, the performance of the device having the electrode applied thereto can be improved.

In other words, the nanowire composition according to the embodiment and the electrode structure fabricated by using the nanowire composition can represent the high dispersibility and the high coating property, and can maintain the high transmittance. The electrode structure has the low reflectance, the high conductivity, the high light transmittance, and the low haze. In addition, the electrode represents the low surface resistance, so that the performance of the device having the electrode applied thereto can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A nanowire composition comprising a metallic nanowire, an organic binder, a surfactant, and a solvent, wherein the metallic nanowire has a diameter of 30 nm to 50 nm, a length of 15 μm to 40 μm, and a weight percentage in a range of 0.01% to 0.4%,
wherein the organic binder has a weight percentage in a range of 0.01% to 0.5%.

2. The nanowire composition of claim 1, wherein the surfactant includes a fluorine-based surfactant or a silicon-based surfactant.

3. The nanowire composition of claim 1, wherein the metallic nanowire includes a silver nanowire.

4. The nanowire composition of claim 1, wherein the organic binder includes hydroxy propyl methyl cellulose, hydroxy propyl cellulose, methyl cellulose, xanthan gum, polyvinyl alcohol, carboxyl methyl cellulose, or hydroxy ethyl cellulose.

5. (canceled)

6. The nanowire composition of claim 1, wherein the metallic nanowire has a weight percentage equal to a weight percentage of the organic binder.

7. The nanowire composition of claim 1, wherein the surfactant has a weight percentage in a range of 0.000001% to 0.001%.

8. The nanowire composition of claim 5, wherein the surfactant has a weight percentage in a range of 0.0002 weight % to 10 weight % with respect to the metallic nanowire.

9. A method of fabricating a transparent electrode, the method comprising:
preparing a nanowire composition;
coating the nanowire composition on a substrate; and
performing heat treatment with respect to the nanowire composition,
wherein the nanowire composition comprises a metallic nanowire, an organic binder, a surfactant, and a solvent, and the metallic nanowire has a diameter of 30 nm to 50 nm, a length of 15 μm to 40 μm, and a weight percentage of 0.01% to 0.4%,
wherein the organic binder has a weight percentage in a range of 0.01% to 0.5%.

10. The method of claim 9, wherein the surfactant includes a fluorine-based surfactant or a silicon-based surfactant.

11. The method of claim 9, wherein the metallic nanowire includes a silver nanowire.

12. The method of claim 9, wherein the organic binder includes hydroxy propyl methyl cellulose, hydroxy propyl cellulose, methyl cellulose, xanthan gum, polyvinyl alcohol, carboxyl methyl cellulose, or hydroxy ethyl cellulose.

13. (canceled)

14. The method of claim 9, wherein the surfactant has a weight percentage in a range of 0.000001% to 0.001%.

15. The method of claim 9, wherein the surfactant has a weight percentage in a range of 0.0002 weight % to 10 weight % with respect to the metallic nanowire.

16. The method of claim 9, wherein the heat treatment is performed at a temperature of 50° C. to 150° C.

17. The method of claim 9, further comprising forming an over coating layer.

18. A transparent conductive base comprising a transparent electrode fabricated through a nanowire composition according to claim 1.

19. The transparent conductive base of claim 18, further comprising an over coating layer.
